(19) United States
(12) Patent Application Publication
(10) Pub. No.: US 2017/0191162 A1
(43) Pub. Date: Jul. 6, 2017

(54) COATING APPARATUS FOR CONTINUOUSLY FORMING A FILM THROUGH CHEMICAL VAPOR DEPOSITION

(71) Applicant: METAL INDUSTRIES RESEARCH AND DEVELOPMENT CENTRE, KAOHSIUNG (TW)

(72) Inventors: TING-PIN CHO, KAOHSIUNG (TW); WEN-CHENG KUO, KAOHSIUNG (TW); KUNG-MING HSU, KAOHSIUNG (TW); CHING-FU YANG, KAOHSIUNG (TW); JYH-NAN SHIEH, KAOHSIUNG (TW)

(21) Appl. No.: 14/984,641

(22) Filed: Dec. 30, 2015

(51) Int. Cl. C23C 16/46; C23C 16/455

(52) U.S. Cl. CPC C23C 16/46; C23C 16/455

(57) ABSTRACT

A coating apparatus for continuously forming a film through chemical vapor deposition (CVD) includes a conveyor unit for conveying a substrate along a moving path, a deposition unit and a film formation-prohibiting unit. The deposition unit is disposed on the moving path and includes a deposition chamber adapted for receiving the substrate and forming a film on the substrate through CVD. The film formation-prohibiting unit includes a heating mechanism that is disposed in the deposition chamber for maintaining the conveyor unit at a film formation-prohibiting temperature.

### FIELD

The disclosure relates to a coating apparatus, more particularly to a coating apparatus for continuously forming a film through chemical vapor deposition.

### BACKGROUND

Referring to FIG. 1, a continuous coating apparatus 1 described in Taiwanese utility model patent No. M503419, entitled “Continuous Coating Device for Chemical Vapor Deposition Film with High Uniformity,” includes a conveyor unit 11 for conveying a roll-shaped substrate 100, a deposition unit 12, a condensation unit 13 connected to the deposition unit 12, and an accommodation unit 14 for accommodating the conveyor unit 11. The conveyor unit 11 is configured as a roll-to-roll mechanism and includes a substrate supply roller and a take-up roller so as to continuously form a film through Chemical Vapor Deposition (CVD). However, if the conveyor unit 11 is not configured as a roll-to-roll mechanism and instead, the substrate 100 is placed on the conveyor unit 11, the deposition unit 12 tends to form films through the CVD on both the substrate 100 and the conveyor unit 11. As the result, the apparent size of the conveyor unit 11 will gradually change and the conveyor unit 11 will finally malfunction and become unable to convey the substrate 100.

Although, through periodic cleaning or replacement of the conveyor unit 11, malfunction of the conveyor unit 11 can be avoided, periodic cleaning or replacement of the conveyor unit 11 is both time- and manpower-consuming, increasing the production cost and adversely affecting the overall production capacity.

### SUMMARY

According to the disclosure, a coating apparatus for continuously forming a film through chemical vapor deposition (CVD) includes a conveyor unit for conveying a substrate along a moving path, a deposition unit and a film formation-prohibiting unit.

The deposition unit is disposed on the moving path and includes a deposition chamber adapted for receiving the substrate and forming a film on the substrate through CVD.

The film formation-prohibiting unit includes a heating mechanism that is disposed in the deposition chamber for maintaining the conveyor unit at a film formation-prohibiting temperature.

### BRIEF DESCRIPTION OF THE DRAWINGS

Other features and advantages of the disclosure will become apparent in the following detailed description of the embodiments with reference to the accompanying drawings, of which:

FIG. 1 is a schematic view for illustrating a conventional coating apparatus described in Taiwanese utility model patent No. M503419;

FIG. 2 is a schematic view for illustrating a first embodiment of a coating apparatus for continuously forming a film through CVD according to the disclosure;

FIG. 3 is a schematic view for illustrating a conveyor unit and a heating mechanism of the first embodiment;

FIG. 4 is a partial schematic view for illustrating a second embodiment of a coating apparatus for continuously forming a film through CVD according to the disclosure;

FIG. 5 is a schematic view for illustrating a second embodiment of a coating apparatus for continuously forming a film through CVD according to the disclosure;

FIG. 6 is a schematic view for illustrating a conveyor unit and a heating mechanism of the third embodiment;

FIG. 7 is a schematic view for illustrating a modified configuration of the heating mechanism of the third embodiment;

FIG. 8 is a partial schematic view for illustrating a fourth embodiment of a coating apparatus for continuously forming a film through CVD according to the disclosure; and

FIG. 9 is a schematic view for illustrating a modified configuration of the heating mechanism of the fourth embodiment.

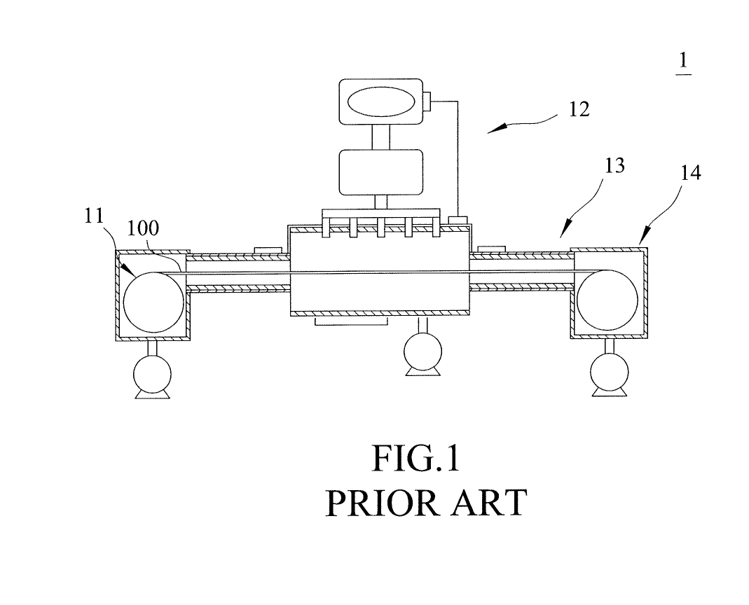

### DETAILED DESCRIPTION

Before the disclosure is described in greater detail with reference to the accompanying embodiments, it should be noted herein that like elements are denoted by the same reference numerals throughout the disclosure.

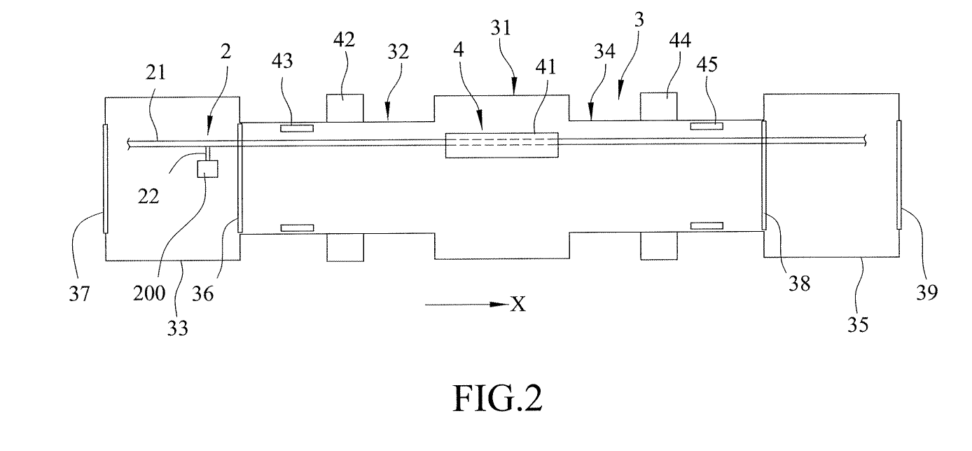

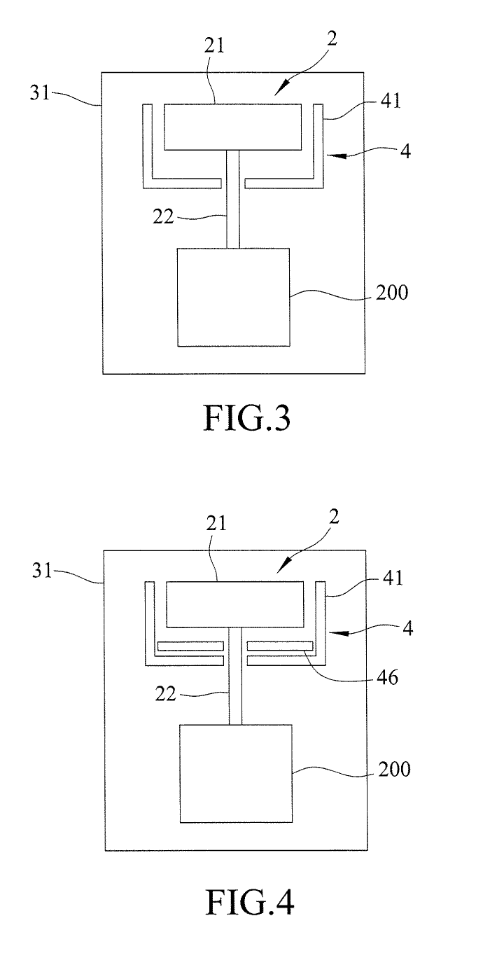

Referring to FIGS. 2 and 3, a coating apparatus for continuously forming a film through CVD according to the first embodiment of the disclosure includes a conveyor unit 2 for conveying a substrate 200 along a moving path (X), a deposition unit 3 disposed on the moving path (X), and a film formation-prohibiting unit for maintaining the conveyor unit 2 at a film formation-prohibiting temperature. The conveyor unit 2 includes a conveyor mechanism 21 that is movable along the moving path (X) and a connection mechanism 22 that detachably connects the substrate 200 and the conveyor mechanism 21. In this embodiment, the conveyor mechanism 21 is a suspensory conveyor device and the connection mechanism 22 is configured as a hanger to be detachably hung with the substrate 200.

The deposition unit 3 includes, arranged sequentially along the moving path (X), an inlet chamber 33, an inlet connection chamber 32 that is in spatial communication with the inlet chamber 33, a deposition chamber 31 that is in spatial communication with the inlet connection chamber 32 and adapted for receiving the substrate 200 and forming a film on the substrate 200 through CVD, an outlet connection chamber 34 that is in spatial communication with the deposition chamber 31, and an outlet chamber 35 that is in spatial communication with the outlet connection chamber 34. The deposition unit 3 further includes an inlet connection gate 36 that is disposed between the inlet connection chamber 32 and the inlet chamber 33 for permitting entry of the substrate 200 into the inlet connection chamber 32, an inlet gate 37 that is disposed on the inlet chamber 33 and spaced apart from the inlet connection gate 36 for permitting entry of the substrate 200 into the inlet chamber 33, an outlet connection gate 38 that is disposed between the outlet connection chamber 34 and the outlet chamber 35 for permitting entry of the substrate 200 into the outlet connection chamber 34, and an outlet gate 39 that is disposed at the outlet chamber 35 and spaced apart from the outlet connection gate 38 for permitting exiting of the substrate 200 out of the outlet chamber 35. By way of example, the deposition chamber 31 may be used for forming a poly-para-xylene (poly-p-xylene) film on the substrate 200, and the inlet connection gate 36, the inlet gate 37, the outlet connection gate 38 and the outlet gate 39 may all be gate valves.

The film formation-prohibiting unit 4 includes a heating mechanism 41 that is disposed in the deposition chamber 31 at a position corresponding to the conveyor unit 2 so as to maintain the conveyor unit 2 at a film formation-prohibiting temperature, at which formation of the film through CVD on the conveyor unit 2 hardly occurs, an inlet heating mechanism 42 that is disposed in the inlet connection chamber 32, and an inlet condensation mechanism 43 that is disposed in the inlet connection chamber 32 and spaced apart from the inlet heating mechanism 42, an outlet heating mechanism 44 that is disposed in the outlet connection chamber 34, and an outlet condensation mechanism 45 that is disposed in the outlet connection chamber 34 and spaced apart from the outlet heating mechanism 44. In one configuration, the inlet heating mechanism 42 is disposed between the inlet condensation mechanism 43 and the deposition chamber 31, the outlet heating mechanism 44 is disposed between the outlet condensation mechanism 45 and the deposition chamber 31. The heating mechanism 41 is proximate to the conveyor mechanism 21 so as to cover the conveyor mechanism 21. As an example, the heating mechanism 41 is a two-piece heating seat that is disposed between the substrate 200 and the conveyor mechanism 21 and has a substantially U-shaped longitudinal cross section. However, for conforming to the design of a conveyor table of the conveyor mechanism 21, the heating mechanism 41 may only cover a lower portion of the conveyor mechanism 21, or may circumferentially enclose the conveyor mechanism 21 as long as the operation of the conveyor mechanism 21 is not interfered. Moreover, based on the chemical properties of poly-p-xylene, film formation through CVD hardly occurs at a temperature higher than 60° C. and occurs quickly at a temperature lower than −60° C. For this reason, the film formation-prohibiting temperature and the temperatures of the inlet heating mechanism 42 and the outlet heating mechanism 44 each range from 60° C. to 150° C., and the temperatures of the inlet condensation mechanism 43 and the outlet condensation mechanism 45 each range from −60° C. to −150° C. As an example, the temperature of the outlet heating mechanism 44 is 100° C. and the temperature of the outlet condensation mechanism 45 is −100° C.

By way of example, when the coating apparatus is used to form the poly-p-xylene film on the substrate 200, the inlet connection gate 36, the inlet gate 37, the outlet connection gate 38 and the outlet gate 39 are closed and then, the deposition chamber 31, the inlet chamber 33 and the outlet chamber 35 are evacuated to a pressure of 3 mTorr.

Next, the heating mechanism 41 is heated to the film formation-prohibiting temperature. The inlet heating mechanism 42 and the outlet heating mechanism 44 are heated to 100° C. The inlet condensation mechanism 43 and the outlet condensation mechanism 45 are cooled to −100° C.

Thereafter, the inlet gate 37 is opened and the substrate 200 is conveyed by the conveyor mechanism 21 to the inlet chamber 33, followed by closing the inlet gate 37 and evacuating the inlet chamber 33 to the pressure of 3 mTorr. Subsequently, the inlet connection gate 36 is opened and the substrate 200 is conveyed by the conveyor mechanism 21 to the deposition chamber 31, followed by closing the inlet connection gate 36.

Para-xylene (p-xylene) monomers are introduced into the deposition chamber 31 and the deposition chamber 31 is controlled to be maintained at a pressure of 40 mTorr so as to form the poly-p-xylene film on the substrate 200 through CVD. After the film formation is conducted for a predetermined time period, introduction of the p-xylene monomers into the deposition chamber 31 is terminated. Through radiation heat generated by the heating mechanism 41 that is maintained at the temperature of 100° C., the periphery of the conveyor mechanism 21 is heated so as to prevent the p-xylene monomers from being deposited on the conveyor mechanism 21 to form a poly-p-xylene film thereon.

Thereafter, the outlet connection gate 38 is opened and the substrate 200 coated with the poly-p-xylene film is conveyed to the outlet chamber 35. Next, the outlet connection gate 38 is closed and the outlet gate 39 is opened so as to move the substrate 200 coated with the poly-p-xylene film out of the outlet chamber 35.

By sequentially repeating opening and closing operations of the inlet connection gate 36, the inlet gate 37, the outlet connection gate 38 and the outlet gate 39, the vacuum of the deposition chamber 31 is able to be maintained for continuously forming the poly-p-xylene film on the substrate 200.

Through radiation heat generated by the inlet heating mechanism 42 and the outlet heating mechanism 44 that are maintained at the temperature of 100° C., the pollution of the p-xylene monomers that overflow from the deposition chamber 31 into the inlet connection chamber 32 and the outlet connection chamber 34 can be avoided. Moreover, since the inlet condensation mechanism 43 and the outlet condensation mechanism 45 are maintained at the temperature of −100° C., trace amount of the p-xylene monomers passing through the inlet heating mechanism 42 and the outlet heating mechanism 44 can be captured. Not only pollution of the overflowing p-xylene monomers in the inlet chamber 33 and the outlet chamber 35 but also outflow of the p-xylene monomers through the inlet gate 37 and the outlet gate 39 can be avoided so as to provide a dual protection effect. In addition, detachable connection of the connection mechanism 22 between the conveyor mechanism 21 and the substrate 200 is advantageous to cleaning and replacement of the connection mechanism 22.

Referring to FIG. 4, the second embodiment of a coating apparatus for continuously forming a film through CVD of the disclosure is similar to the first embodiment. However, the film formation-prohibiting unit 4 of the second embodiment further includes a pair of adsorption mechanisms 46 that are disposed in the deposition chamber 31 and that are able to be maintained at an adsorption temperature at which formation of a film through CVD can be carried out on the adsorption mechanisms 46. As an example, the adsorption mechanisms 46 are configured as a pair of condensation plates that are disposed between the heating mechanism 41 and the conveyor mechanism 21 with the connection mechanism 22 interposed therebetween, and the adsorption temperature is −100° C.

In view of the similarity between the first and second embodiments, in addition to the effect achievable by the first embodiment, trace amount of the p-xylene monomers passing through the relatively high radiation heat area full of the radiation heat generated by the heating mechanism 41 can be selectively and quickly coated on the adsorption mechanisms 46 due to location of the adsorption mechanisms 46 adjacent to the conveyor mechanism 21 and the adsorption temperature of the adsorption mechanisms 46 much lower than the condensing temperature of the conveyor mechanism 21. The effect of prohibiting formation of the poly-p-xylene film on the conveyor mechanism 21 can be enhanced.

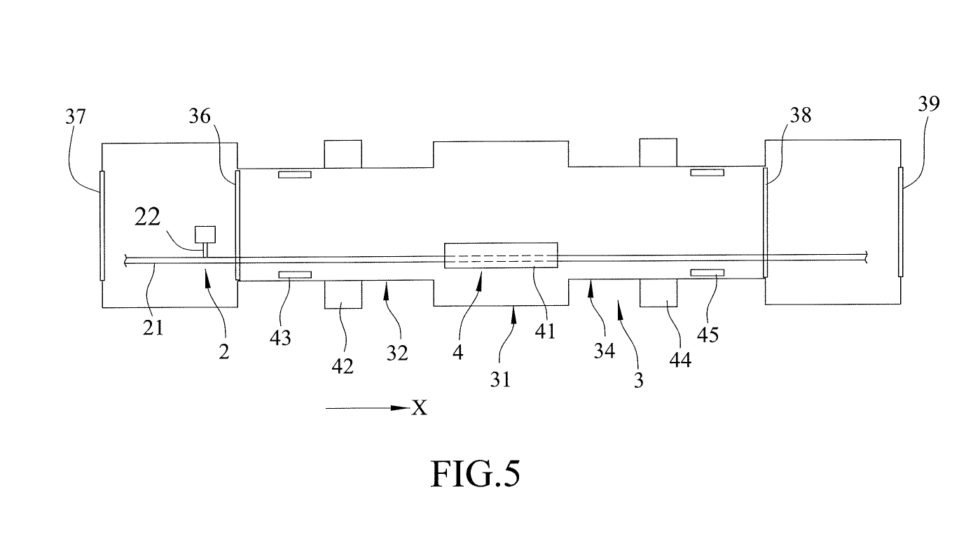

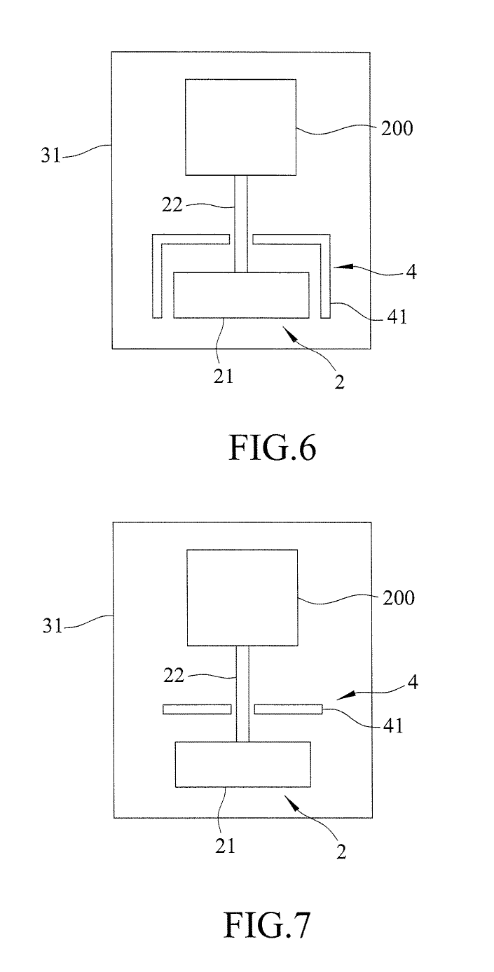

Referring to FIGS. 5 and 6, the third embodiment of a coating apparatus for continuously forming a film through CVD of the disclosure is similar to the first embodiment. However, the conveyor mechanism 21 is configured as a conveyor belt and the connection mechanism 22 is configured as a support post that is detachably disposed on the conveyor mechanism 21 for supporting the substrate 200.

Moreover, in this embodiment, the heating mechanism 41 is configured as a heating seat having an inverted U-shaped longitudinal cross section. Alternatively, the heating mechanism 41 maybe configured as a heating board as shown in FIG. 7.

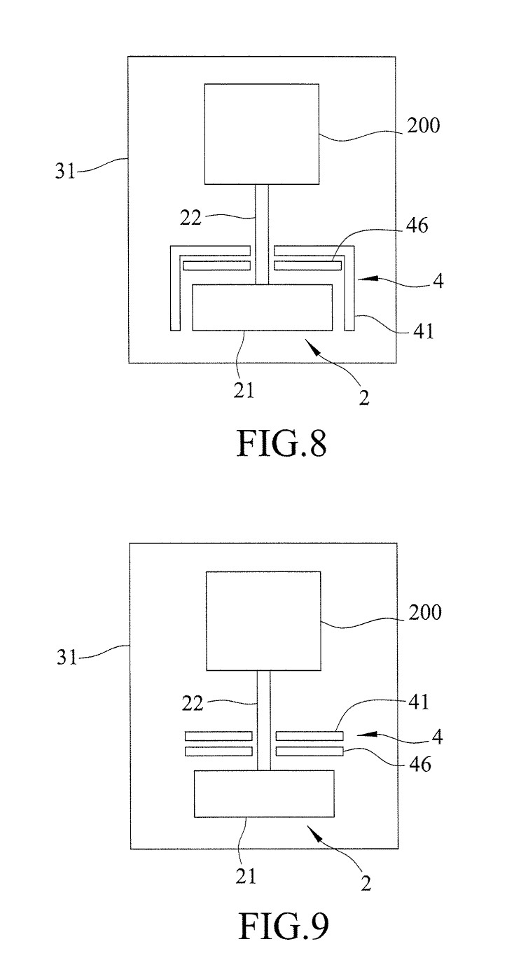

Referring to FIG. 8, the fourth embodiment of a coating apparatus for continuously forming a film through CVD of the disclosure is similar to the third embodiment. However, the film formation-prohibiting unit 4 further includes a pair of adsorption mechanisms 46 that are disposed in the deposition chamber 31 at positions corresponding to the conveyor unit 2 and maintained at the adsorption temperature. As an example, the adsorption mechanisms 46 are configured as a pair of condensation plates that are disposed between the heating mechanism 41 and the conveyor mechanism 21 with the connection mechanism 22 interposed therebetween, and the adsorption temperature is −100° C. Alternatively, the heating mechanism 41 may be configured as a heating board as shown in FIG. 9, instead of the heating seat as shown in FIG. 8.

In sum, by virtue of heating the conveyor unit 2 to the film formation-prohibiting temperature by the heating mechanism 41, film formation on the conveyor unit 2 is prevented from occurring while film formation is carried out on the substrate 200. Therefore, malfunction in the conveyor unit 2 due to a change in the apparent size thereof can be avoided. The cleaning or replacement frequency of the conveyor unit 2 can be reduced. Thereby, the maintenance cost is greatly reduced and production capacity thereof can be enhanced.

While the disclosure has been described in connection with what are considered the practical embodiments, it is understood that this disclosure is not limited to the disclosed embodiments but is intended to cover various arrangements included within the spirit and scope of the broadest interpretation so as to encompass all such modifications and equivalent arrangements.

This disclosure is not limited to the disclosed exemplary embodiments but is intended to cover various arrangements included within the spirit and scope of the broadest interpretation so as to encompass all such modifications and equivalent arrangements.

What is claimed is:

1. A coating apparatus for continuously forming a film through chemical vapor deposition (CVD), comprising:
a conveyor unit for conveying a substrate along a moving path;
a deposition unit that is disposed on the moving path and includes a deposition chamber adapted for receiving the substrate and forming a film on the substrate through CVD; and
a film formation-prohibiting unit that includes a heating mechanism disposed in said deposition chamber for maintaining said conveyor unit at a film formation-prohibiting temperature.

2. The coating apparatus for continuously forming the film through CVD of claim 1, wherein said film formation-prohibiting unit further includes at least one adsorption mechanism that is disposed in said deposition chamber and maintained at an adsorption temperature at which formation of a film through CVD can be carried out on said adsorption mechanism.

3. The coating apparatus for continuously forming the film through CVD of claim 2, wherein said deposition unit further includes, arranged along the moving path X, an inlet connection chamber that is in spatial communication with said deposition chamber and an inlet chamber that is in spatial communication with said inlet connection chamber, said film formation-prohibiting unit further including an inlet heating mechanism that is disposed in the inlet connection chamber and an inlet condensation mechanism that is disposed in said inlet connection chamber and spaced apart from said inlet heating mechanism, said inlet heating mechanism being interposed between said inlet condensation mechanism and said deposition chamber, the substrate being conveyed from said inlet chamber to said deposition chamber by said conveyor unit.

4. The coating apparatus for continuously forming the film through CVD of claim 3, wherein said deposition unit further includes, arranged along the moving path X, an outlet connection chamber that is in spatial communication with said deposition chamber and an outlet chamber that is in spatial communication with said outlet connection chamber, said film formation-prohibiting unit further including an outlet heating mechanism that is disposed in said outlet connection chamber and an outlet condensation mechanism that is disposed in said outlet connection chamber and spaced apart from said outlet heating mechanism, said outlet heating mechanism being interposed between said outlet condensation mechanism and said deposition chamber, the substrate being conveyed from said inlet chamber to said outlet chamber through said deposition chamber by said conveyor unit.

5. The coating apparatus for continuously forming the film through CVD of claim 4, wherein said deposition unit further includes an inlet connection gate that is disposed between said inlet connection chamber and said inlet chamber for permitting entry of the substrate into said inlet connection chamber, and an inlet gate that is disposed on said inlet chamber and spaced apart from said inlet connection gate for permitting entry of the substrate into said inlet chamber and.

6. The coating apparatus for continuously forming the film through CVD of claim 5, wherein said deposition chamber further includes an outlet connection gate that is disposed between said outlet connection chamber and said outlet chamber for permitting entry of the substrate into said outlet connection chamber, and an outlet gate that is disposed at said outlet chamber and spaced apart from said outlet connection gate for permitting exiting of the substrate out of said outlet chamber.

7. The coating apparatus for continuously forming the film through CVD of claim 6, wherein said film formation-prohibiting temperature ranges from 60° C. to 150° C., said adsorption temperature ranging from −60° C. to −150° C.

8. The coating apparatus for continuously forming the film through CVD of claim 6, wherein said inlet heating mechanism and said outlet heating mechanism each have temperatures ranging from 60° C. to 150° C., said inlet condensation mechanism and said outlet condensation mechanism each having temperatures ranging from −60° C. to −150° C.

9. The coating apparatus for continuously forming the film through CVD of claim 2, wherein said conveyor unit includes a conveyor mechanism and a connection mechanism that detachably connects the substrate and said conveyor mechanism, said heating mechanism being disposed between said conveyor mechanism and the substrate and adjacent to said conveyor mechanism, said adsorption mechanism being disposed between said heating mechanism and said conveyor mechanism.

10. The coating apparatus for continuously forming the film through CVD of claim 9, wherein said film formation-prohibiting unit includes a pair of said adsorption mechanisms that are disposed in said deposition chamber with said connection mechanism interposed therebetween.
